(19) United States
(12) Patent Application Publication
(10) Pub. No.: US 2006/0260677 A1
(43) Pub. Date: Nov. 23, 2006

(54) Polypropylene silicate nanocomposites

(75) Inventors: Dotsevi Y. Sogah, Ithaca, NY (US); Xiao-Ping Chen, Bellmore, NY (US); Hyuk Lee, Seoul (KR); Geoffrey W. Coates, Ithaca, NY (US)

Correspondence Address: BACON & THOMAS, PLLC, 625 SLATERS LANE, FOURTH FLOOR, ALEXANDRIA, VA, 22314, US

(73) Assignee: Cornell Research Foundation, Inc., Ithaca, NY (US)

(21) Appl. No.: 11/435,867

(22) Filed: May 18, 2006

Related U.S. Application Data
(60) Provisional application No. 60/683,346, filed on May 23, 2005.

(51) Int. Cl. H01L 31/00

(52) U.S. Cl. 136/253

(57) ABSTRACT

Nanoadditive is constituted of organophilic polymer or copolymer covalently bonded by linking group to silicate and is blended with polypropylene to produce nanocomposite which is useful in all cases where polypropylene is used and resists breakage and is not flammable and has improved barrier properties compared to neat polypropylene.

### CROSS-REFERENCE TO RELATED APPLICATIONS

This application claims the benefit of U.S. Provisional Patent Application No. 60/683,346, filed May 23, 2005, the whole of which is incorporated herein by reference.

This work was supported at least in part by the Cornell Center for Materials Research, a National Science Foundation-funded MSERC (DMR-0079992). The government has certain rights in the invention.

### TECHNICAL FIELD

This invention is directed at nanocomposite of polypropylene and nanoclay.

### BACKGROUND OF THE INVENTION

Polypropylene, while very attractive for many uses, has the disadvantage that its brittleness, flammability and poor gas barrier properties limit its application. Formation of a polymer layered silicate nanocomposite is expected to be a practical approach to enhancing resistance to breakage and to impart flammability resistance and to improve gas barrier properties. However, because of its high hydrophobicity, polypropylene is incompatible with neat hydrophilic clay. Maleic anhydride grafted polypropylene has been used in place of propylene to increase compatibility with silicate surface; however, this combination results in dramatically reduced elongation in comparison to neat polypropylene. To date, no polypropylene layered silicate nanocomposite has been reported where elongation was increased dramatically and toughness was increased while Young's modulus decreased less than 20%.

### SUMMARY OF THE INVENTION

In one embodiment herein, denoted the first embodiment, the invention is directed at nanoadditive (masterbatch) useful to prepare nanocomposites of the second, third and fourth embodiments of the invention herein, comprising organophilic polymer or copolymer containing at least one linking group per chain and covalently bonded via said linking group to silicate, where the silicate content ranges from 5% to 50% by weight.

In another embodiment herein, denoted the second embodiment, the invention is directed to nanocomposite comprising from 99 to 90%, e.g., 98 to 90% by weight polypropylene having Mₙ ranging from 5,000 to 4,000,000 grams per mole, and from 1 to 10%, e.g., 2 to 10% by weight nanoclay where silicate layers are exfoliated and the degree of exfoliation is preserved despite extrusion at 200° C. and microinjection at 230° C.

In another embodiment herein, denoted the third embodiment, the invention is directed to nanocomposite comprising from 99 to 90%, e.g., 98 to 90% by weight polypropylene having Mₙ ranging from 5,000 to 4,000,000 grams per mole, and from 1 to 10%, e.g., 2 to 10% by weight nanoclay where toughness is increased at least 10% while Young's modulus is decreased less than 15%, compared to neat polypropylene. In a preferred case elongation is increased at least 25%.

In another embodiment herein, denoted the fourth embodiment, the invention is directed at nanocomposite comprising the nanoadditive of the first embodiment herein blended with polypropylene having Mₙ ranging from 5,000 to 4,000,000 grams per mole, with the weight ratio of said polypropylene to said nanoadditive ranging from 20:1 to 1:1.

In another embodiment herein, denoted the fifth embodiment, the invention is directed at epoxy or cyclic anhydride or lactone or amine or alcohol or acid functionalized poly(propylene-co-hexadiene) copolymer having Mₙ ranging from 5,000 to 2,000,000 grams per mole and PDI ranging from 1.1 to 3, useful for preparing nanoadditive of the first embodiment herein.

In another embodiment herein, denoted the sixth embodiment, the invention is directed at a method useful to prepare nanoadditive of the fifth embodiment herein.

In another embodiment herein, denoted the seventh embodiment, the invention is directed at a method useful to prepare nanocomposite of the second, third and fourth embodiments herein.

As used herein, the term “nanocomposite” means composition of nanoclay (silicate) in a polymer matrix.

The term “nanoclay” as used herein to means clay having nanometer thickness silicate platelets that can be modified to make clay complexes compatible with organic monomers and polymers. The term “silicate layers” as used herein refers to the nanometer thickness silicate platelets.

The term “nanoadditive” is used here to mean a nanocomposite of nanoclay in a polymer or copolymer where silicate is dispersed in a matrix of polymer or copolymer for use for blending with polypropylene to confer increase in elongation and toughness while preserving Young's modulus, and to confer flammability resistance and improved barrier properties thereto.

The “elongation” referred to is sometimes called engineering strain and is defined as extension per unit length and is determined using an Instron apparatus and ASTM D638 “Standard test method for tensile properties of plastics”.

The “toughness” referred to is defined as the area under a tensile stress strain curve and is determined using an Instron apparatus and ASTM D638 “Standard test method for tensile properties of plastics”.

Young's modulus referred to herein means tensile modulus and is obtained by taking the initial slope of a tensile stress strain curve determined using an Instron apparatus and ASTM D638 “Standard test method for tensile properties of plastics”.

The “tensile strength” referred to herein is also known as tensile or engineering stress and is defined as the force per unit cross sectional area of the sample and is determined using an Instron apparatus and ASTM D638 “Standard test method for tensile properties of plastics”.

Mₙand PDI as set forth herein are obtained by high temperature gel permeation chromatography relative to polystyrene standards.

### DETAILED DESCRIPTION

We turn now to the first embodiment.

The linking group comprises for example, reaction product of group A of group A functionalized organophilic polymer or copolymer and group B of group B functionalized silicate. The linking group also comprises an organic spacer moiety comprising 1 to, for example, 36, carbon atoms and group bonding to silicate where the organic spacer moiety separates residue of group B from group bonding to silicate. The group bonding to silicate is preferably ammonium. There is really no true maximum for the number of carbon atoms in the organic spacer moiety. For example, the organic spacer moiety can be polyethylene containing group B and ammonium; a requirement is that group B functionalization of silicate can occur in water or acidified water.

The organophilic polymer or copolymer can be, for example, (a) poly(C₂-C₄-α-olefin-co-hexadiene) copolymer having Mₙ ranging from 5,000 to 2,000,000 grams per mole and PDI, for example, ranging from 1.1 to 3, e.g., poly(propylene-co-hexadiene), (b) polypropylene having Mₙ ranging from 5,000 to 4,000,000 grams per mole, or (c) that of commercially available group A functionalized organophilic polymer or copolymer, e.g., that of glycidyl methacrylate having Mₙ ranging from 5,000 to 1,000,000 grams per mole.

The silicate referred to is that of a nanoclay. The nanoclay is preferably montmorillonite, a naturally occurring nanoclay. Other useful nanoclays include, for example, fluorohectorite, laponite, bentonites, beidellites, hectorites, saponites, nontronites, sauconites, vermiculites, ledikites, nagadiites, kenyaites and stevensites.

The nanoclay used for experimentation herein was Cloisite® Na⁺ obtained from Southern Clay Products, Inc., Texas. It is described as a natural montmorillonite and has a dry particle size of 90% less than 13 microns.

Group A is preferably selected from the group consisting of epoxide, cyclic anhydride, lactone, amine, alcohol and acid containing moieties.

Group B is preferably selected from the group consisting of alkoxide, amine, acid, ester, aldehyde, ketone, and lactone containing moieties.

When group A is epoxide containing moiety, group B is selected from the group consisting of alkoxide, amine and acid containing moieties. When group A is cyclic anhydride containing moiety, group B is selected from the group consisting of alkoxide and amine containing moieties. When group A is lactone containing moiety, group B is selected from the group consisting of alkoxide and amine containing moieties. When group A is amine containing moiety, group B is selected from the group consisting of acid, ester, aldehyde, ketone and lactone containing moieties. When group A is alcohol containing moiety, group B is selected from the group consisting of acid, ester, aldehyde, ketone and lactone containing moieties. When group A is acid containing moiety, group B is selected from the group consisting of alkoxide and amine containing moieties.

A starting point for the epoxide, amine, alcohol and acid containing moiety functionalized poly(propylene-co-hexadiene) copolymer is vinyl functionalized poly(propylene-co-hexadiene) copolymer which is III in WO 2004/067589 A1, the whole of which is incorporated herein by reference, and its continuation-in-part published as Publication No. US-2005-0239966-A1. The preparation of III is described in WO 2004/067589 A1 and US-2005-0239966-A1. The vinyl functionalized poly(propylene-co-hexadiene) copolymer used in experiments herein was prepared using a catalyst system of (F₅-PHI)₂ TiCl₂ and MAO as described in WO 2004/067589A1 and polypropylene block is preferably at least 90%, very preferably at 96%, syndiotactic.

Epoxide containing moiety functionalized poly(propylene-co-hexadiene) copolymer is made by reacting the vinyl functionalized poly(propylene-co-hexadiene) with meta chloro peroxy benzoic acid (MCPBA). The epoxy functional groups are preferably present in a block at one end of a chain.

Amine containing moiety functionalized copolymer can be made by opening the epoxide with an amine.

Alcohol containing moiety functionalized copolymer can be made by opening the epoxide using an amine nucleophile to generate alcohol moiety.

Acid, e.g., carboxylic acids, containing moiety functionalized copolymer can be made by reacting the alcohol produced in the paragraph directly above with succinic or maleic anhydride.

Cyclic anhydride containing moiety functionalized polypropylene can be made by grafting maleic anhydride to polypropylene. Cyclic anhydride functionalized polypropylene is also available commercially. Cyclic anhydride containing moiety functionalized copolymer can be made by grafting maleic anhydride to either the polypropylene block or the hexadiene block using known literature procedures.

Lactone containing moiety functionalized polypropylene can be made by grafting an olefin containing lactone to polypropylene. Lactone containing moiety functionalized copolymer can be made by grafting an olefin containing lactone to either the polypropylene block or the hexadiene block using know literature procedures.

Structure of a vinyl functionalized poly(propylene-co-hexadiene) copolymer is schematically depicted below.

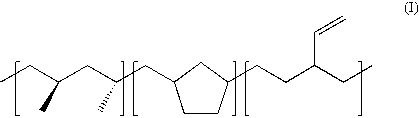

Structure of an epoxide containing moiety functionalized poly(propylene-co-hexadiene) copolymer is schematically depicted below.

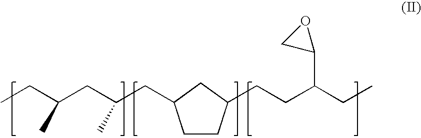

Structure of an anhydride containing moiety functionalized poly(propylene-co-hexadiene) is schematically depicted below.

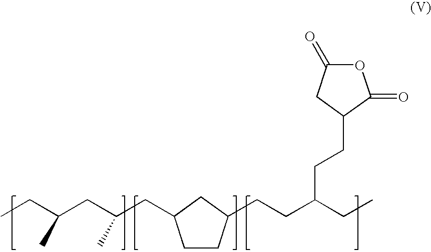

Structure for a carboxylic acid containing moiety functionalized poly(propylene-co-hexadiene) is schematically depicted below.

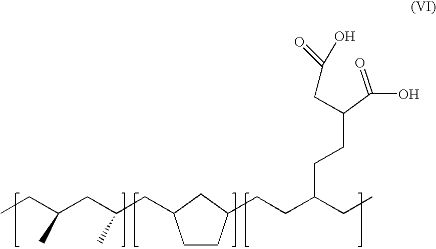

Structure for a lactone containing moiety functionalized poly(propylene-co-hexadiene) is schematically depicted below.

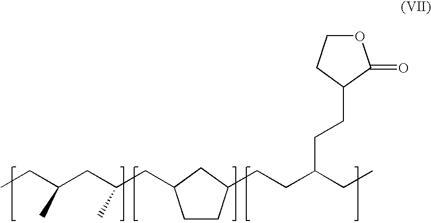

We turn now to the group B functionalized silicate.

It can be, for example, 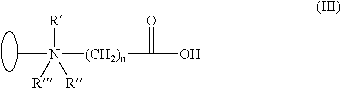
where the ellipse shaped structure represents nanoclay anion, n ranges from 1 to, for example, 36,(see comment on polyethylene spacer above), and R¹, R¹¹ and R¹¹¹ are independently selected from the group consisting of hydrogen atom and alkyl group containing from 1 to 18 carbon atoms and arylalkyl group containing from 7 to 15 carbon atoms. Structure (III) represents acid containing moiety functionalized silicate.

A functionalized silicate (III), can be prepared, for example, by ion exchanging 12-aminododecanoic acid with nanoclay (e.g., montmorillonite) in the sodium form under acidic conditions (e.g., acidified with 1 eq. HCl), in water; or by ion exchanging glycine (to provide n=1) with nanoclay (e.g., montmorillonite) in the sodium form (to provide n=11) under acidic conditions (e.g., acidified with 1 eq. HCl, in water). As a substitute for 12-aminododecanoic acid or glycine, an amino acid, e.g., beta-alanine (n=2) is suitable and almost any long chain with amino group at one end and acid group at the other is suitable.

In the case of functionalized silicate (III) there is produced acid containing moiety functionalized silicate where the acid containing moiety (a group B residue (i.e., that which remains of group B after reaction with group A)) is anchored to silicate by an ammonium group which is separated from group B residue by an organic spacer moiety containing from 1 to, for example, 36, carbon atoms.

In a variation of (III), alkylene is replaced with a glycol.

The group B functionalized silicate can also be, for example, 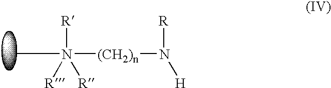
where the ellipse shaped structure represents nanoclay anion, n ranges from 2 to, for example, 36, and R¹, R¹¹ and R¹¹¹ are independently selected from the group consisting of hydrogen atom, alkyl containing from 1 to 18 carbon atoms and arylalkyl containing from 7 to 15 carbon atoms and R is selected from the group consisting of hydrogen, alkyl containing from 1 to 18 carbon atoms, aryl containing from 6 to 20 carbon atoms and arylalkyl containing from 7 to 15 carbon atoms.

A functionalized silicate (IV) can be prepared, for example, by ion exchanging ethylenediamine (to provide n=2) under acidic conditions with nanoclay (e.g., montmorillonite) in the sodium form. In addition to ethylenediamine, poly(propylene glycol)bis(2-aminopropylether), namely CH₃CH(NH₂)CH₂[OCH₂CH(CH₃)]ₙNH₂ where n is at least 2 is suitable; in cases where there is a heteroatom such as O in the spacer as in polyethyleneglycol (CH₂CH₂O)ₙ, n has to be greater than 1. In experiments supporting the invention commercially available poly(propyleneglycol)bis(2-aminopropyl ether where n=5−6 (Mₙ=400 grams per mole), has been used. The poly(ethylenegylcol)bis(2-aminopropyl ether)s are water soluble and have excellent compatibility with a wide range of polar and water-soluble materials.

In the case of functionalized silicate (IV), there is produced amine containing moiety (a group B residue, i.e., that which remains of group B after reaction with group A) is anchored to silicate by an ammonium group which is separated from group B residue by an organic spacer moiety containing from 1 to, e.g., 36, carbon atoms.

To form the nanoadditive of the first embodiment, the group A functionalized organophilic polymer or copolymer can be reacted with the group B functionalized silicate in solvent, e.g., in chloroform, or in a melt process. A suitable reaction in solvent is carried out by refluxing the two components in stoichiometric amounts for 10-30 hours under nitrogen. A suitable melt process reaction is carried out by heating an admixture of the two components in stoichiometric amounts at a temperature ranging, for example, from 160° to 300° under nitrogen. The minimum temperature is the melting point and the maximum is set by the decomposition temperature which is above 400° C.

In the nanoadditive formation reaction, the organophilic polymer or copolymer chains become attached to silicate layers by reaction of group A with group B. This forces more of polymer or copolymer chains to intercalate between layers of silicate causing the silicate layers to exfoliate and become randomly dispersed in the organophilic polymer. As used herein the term “intercalate” means penetrate. As used herein the term “exfoliate” means become delaminated. The exfoliated silicate layers provide resistance to breakage and flammability and improvement in gas barrier property compared to neat polyethylene.

We turn now to the second, third and fourth embodiments herein, i.e., to nanocomposites of the invention herein.

There nanocomposites can be prepared by blending the nanoadditive and polypropylene having Mₙ ranging from 5,000 to 4,000,000 grams per mole in a weight ratio of said polypropylene to nanoadditive ranging from 20:1 to 1:1. This can be carried out by extrusion at 200° C. The blend is microinjected at 230° C. into dog-bone samples for testing. The exfoliation of silicate nanolayers is stable after the blending, thereby imparting to the nanocomposite resistance to breakage and flammability and improved gas barrier properties and higher crystallinity (45% compared to 34% for the original polypropylene). In other words, the silicate layers are exfoliated and the exfoliation is preserved despite extrusion at 200° C. and microinjection at 230° C. The result is a nanocomposite comprising polypropylene where elongation is increased at least 25% and toughness is increased at least 10% while Young's modulus is decreased less than 15%, compared to neat polyethylene. The nanocomposites are useful in all those cases where polypropylene is useful but contrary to the case with polypropylene, the nanocomposite resists breakage and is not flammable.

We turn now to the fifth embodiment herein. This embodiment is directed to group A functionalized organophilic polymers or copolymers for use in preparation of the nanoadditive of the first embodiment and these and their preparation are described above in conjunction with description of the first embodiment.

We turn now to the sixth embodiment herein. This is directed to a method for preparing the nanoadditive of the first embodiment and comprises the step of reacting group A functionalized organophilic polymer or copolymer with group B functionalized silicate where group A and group B react to form silicate covalently bonded to the polymer or copolymer. As above, group A is selected from the group consisting of epoxide, cyclic anhydride, lactone, amine, alcohol and acid, e.g., carboxylic acid, containing moieties and group B is selected from the group consisting of alkoxide, amine, acid, ester, aldehyde, ketone, and lactone containing moieties; where when group A is epoxide containing moiety, group B is selected from the group consisting of alkoxide, amine and acid containing moieties; where when group A is cyclic anhydride containing moiety, group B is selected from the group consisting of alkoxide and amine containing moieties; where when group A is lactone containing moiety, group B is selected from the group consisting of alkoxide and amine containing moieties; where when group A is amine containing moiety, group B is selected from the group consisting of acid, ester, aldehyde, ketone and lactone containing moieties; where when group A is alcohol containing moiety, group B is selected from the group consisting of acid, ester, aldehyde, ketone and lactone containing moieties; and when group A is acid containing moiety, group B is selected from the group consisting of alkoxide and amine containing moieties.

In one exemplified case, the group A functionalized polymer or copolymer is epoxide functionalized poly(propylene-co-hexadiene) having Mₙ ranging from 5,000 to 2,000,000 grams per mole and PDI ranging from 1.1 to 1.3, and the group B functionalized silicate is 12-aminododecanoic acid or glycine ion exchanged under acidic conditions with sodium montmorillonite so that group B is anchored to silicate by an ammonium group.

In another exemplified case, the group A functionalized polymer or copolymer is cyclic anhydride functionalized polypropylene having Mₙranging from 5,000 to 4,000,000 and the group B functionalized silicate is 12-aminododecanoic acid or glycine or poly(propyleneglycol)bis(2-aminopropyl ether) as described above is ion exchanged under acidic conditions with Na-MMT so that group B is anchored to silicate by ammonium group.

This method is described in conjunction with the first embodiment and is exemplified in working examples herein.

We turn now to the seventh embodiment herein.

The method of the seventh embodiment is for preparing nanocomposites of the second, third and fourth embodiments and comprises the step of blending the nanoadditive of the first embodiment with polypropylene having Mₙ ranging from 5,000 to 4,000,000 grams per mole in a weight ratio of said polypropylene to said nanoadditive ranging from 20:1 to 1:1. The blending can be carried out by extruding admixture of nanoadditive and said polypropylene at a temperature ranging from 160° C. to 300° C. Alternatives to extrusion blending are heating the admixture of the nanoadditive and said polypropylene in an oven at a temperature ranging from 1 90° C. to 250° C. either under nitrogen or vacuum for two hours. This method is described in conjunction with the second, third and fourth embodiments herein and in working examples below.

The percentages of silicate content, polypropylene, and nanoclay herein are by weight.

The invention is illustrated in the following working examples:

### WORKING EXAMPLES I

Epoxy containing moiety functionalized poly(propylene-co-hexadiene copolymer) of Mₙ of 36,000 grams per mole and PDI of 1.14 (denoted PP-co-HD-epoxy) was prepared at follows:

Vinyl functionalized poly(propylene-co-hexadiene) copolymer was prepared by the method for forming vinyl functional poly(propylene-co-hexadiene) as described in WO 2004/067589 A1 and Publication No. US-2005-0239966, and particularly as described.

Acid containing moiety functionalized montmorillonite, denoted MMT-COOH, was prepared by reacting sodium montmorillonite (NAMMT) with 12-aminododecanoic acid, previously acidified with hydrochloric acid. Particularly 0.11 g of 12-aminododecanoic acid was added in 20 mL of H₂O containing one equivalent HCl (with respect to the carboxylic acid) and left stirring for 2 hours. The resulting solution was added to a dispersion of 0.5 g MMT in 75 mL of distilled water at 60 to 70° C. with stirring for 4 hours. The modified MMT (designated MMT-COOH) was obtained after filtration, washing with water, and freeze drying. The loading of acid groups was 53.2 meq/100 g MMT based on TGA whereas the cation exchange capacity (CEC) of the natural montmorillonite (MMT) (Cloisite® Na⁺) was 92.6 meq/100 g.

Nanoadditive was prepared in solution as follows: A mixture of PP-co-HD-epoxy and MMT-COOH (about 5:1 w/w) was refluxed in chloroform for 24 hours under N₂ flow and reaction product was precipitated from MeOH. The precipitate was filtered and dried to provide nanoadditive. The silicate content in the nanoadditive was 14.5% by weight.

Nanoadditive was prepared by a melt process as follows: An admixture of PP-co-HD-epoxy and MMT-COOH (about 3:1, w/w) was heated at 190° C. either under nitrogen atmosphere or in a vacuum oven for two hours. The nanoadditive product was obtained on cooling to room temperature. The silicate content in the nanoadditive was 19.6% by weight.

### WORKING EXAMPLE II

Two different cyclic anhydride containing moiety functionalized polypropylenes were purchased from Aldrich Chemical Company.

In one case the polypropylene had Mₙ of 3900 and PDI of 2.33, melting temperature of 156° C. and acid number of 47 mg KOH/g. (Mₙ data from Aldrich).

In the second case the polypropylene had Mₙof 83,300 and PDI of 1.94. It had a melt index of 115 g/10 min. (190° C./2.1 kg), melting temperature of 152° C. and maleic anhydride content of at least 0.6 wt %. (Mₙ data determined).

In the first case, the functionalized polypropylene was denoted L-PP-g-MA, standing for lower molecular weight polypropylene grafted maleic anhydride.

In the second case, the functionalized polypropylene was denoted H-PP-g-MA, standing for higher molecular weight polypropylene grafted maleic anhydride.

MMT-COOH is that described in Working Example I and was prepared as in Working Example I.

Nanoadditive was prepared from L-PP-g-MA and MMT-COOH by a melt process as follows: an admixture of L-PP-g-MA and MMT-COOH (weight ratio of 5:1) was heated at 190° C. under a nitrogen atmosphere for 2 hours. The silicate content in the nanoadditive was 15% by weight.

Nanoadditive was prepared from H-PP-g-MA and MMT-COOH by a melt process as follows: an admixture of H-PP-g-MA and MMT-COOH (weight ratio of 5:1) was heated at 190° C. under a nitrogen atmosphere for 2 hours. The silicate content in the nanoadditive was 15% by weight.

### WORKING EXAMPLE III

Nanocomposite was prepared by blending nanoadditive (14.5% by weight silicate) of Working Example I and polypropylene (isotactic, melt index of 0.5 g/10 min, m.p. 160-165° C., d=0.900, from Aldrich) in a weight ratio of nanoadditive to polypropylene of 1:9 by extruding admixture of nanoadditive and polypropylene at 200° C. for 1 to 3 minutes. Dog-bone shaped samples, denoted samples A, were prepared by microinjection at 230° C. The content of silicate (MMT) in the samples was 1.8% by weight (TGA).

### WORKING EXAMPLE IV

Nanocomposite was prepared by blending nanoadditive of Working Example II prepared by blending L-PP-g-MA, and the commercial polypropylene described in Working Example III in a weight ratio of nanoadditive to polypropylene of 1:6.5 by extruding admixture of nanoadditive and commercial polypropylene at 200° C. Dog-bone shaped samples, denoted samples B, were prepared by microinjection at 230° C. The content of silicate in the samples was 2.5% by weight (TGA).

### WORKING EXAMPLE V

Nanocomposite was prepared by blending nanoadditive of Working Example II prepared by blending H-PP-g-MA, and the commercial polypropylene described in Working Example III in a weight ratio of nanoadditive to polypropylene of 1:6.5 by extruding admixture of nanoadditive and commercial polypropylene at 200° C. Dog-bone shaped samples, denoted samples C, were prepared by microinjection at 230° C. The content of silicate in the samples was 2.5% by weight (TGA).

### WORKING EXAMPLE VI

Mechanical testing was carried out using an Instron tester.

Tests were carried out on Samples A (prepared in Working Example III), Samples B (prepared in Working Example IV), Samples C (prepared in Working Example V), Samples D (the commercial polypropylene described in Working Example III extruded at 200° C. and microinjected at 230° C. into dog-bone shapes), Samples E (blend of the commercial polypropylene and PP-co-HD-epoxy described in Working Example I in a weight ratio of 10.6:1 extruded at 200° C. and microinjected at 230° C. into dog-bone shapes), Samples F (a blend of the commercial polypropylene and L-PP-g-MA described in Working Example II when the L-PP-g-MA is present in an amount of 10% by weight at 200° C. and microinjected at 230° C. into dog-bone shapes), Samples G (a blend of the commercial polypropylene and H-PP-g-MA described in Working Example II where the H-PP-g-MA is present in an amount of 10% by weight, extruded at 200° C. and microinjected into dog-bone shapes at 230° C., Samples H (the blend of samples F also containing 2.5% by weight MMT-COOH extruded at 200° C. and microinjected at 230° C. into dog-bone shapes), Samples I (the blend of Samples G also containing 2.5% by weight MMT-COOH extruded at 200° C. and microinjected at 230° C. into dog-bone shapes).

Results at crosshead speed of 5 mm/min (standard speed) are set forth in Table 1 below.

TABLE 1

| | Samples | | | | | | | | |
|---|---|---|---|---|---|---|---|---|---|
| | A | D | E | F | G | H | I | B | C |
| Elongation | 608.64 | 363.68 | 248.69 | 373.26 | 307.17 | 378.34 | 80.54 | 398.50 | 101.78 |
| (%) | (+67.36%) | | (−31.62%) | (+2.6%) | (−15.5%) | (+4.0%) | (−77.9%) | (+9.6%) | (−72%) |
| Modulus | 915.27 | 1082.22 | 1065 | 944.50 | 960.35 | 1154.53 | 1097.53 | 1019.11 | 1099.90 |
| (Young) | (−15.43%) | | (−1.6%) | (−12.7%) | (−11.3%) | (+6.7%) | (+1.4%) | (−5.8%) | (+1.6%) |
| (MPa) | | | | | | | | | |
| Tensile | 38.13 | 47.47 | 43.61 | 39.14 | 42.29 | 41.47 | 43.60 | 41.56 | 46.02 |
| Strength | (−19.68%) | | (−8.1%) | (−17.5%) | (−10.9%) | (−12.6%) | (−8.2%) | (−12.4%) | (−3.0%) |
| (MPa) | | | | | | | | | |
| Toughness | 196.59 | 158.55 | 101.46 | 135.32 | 121.29 | 147.46 | 32.75 | 155.60 | 44.03 |
| (MPa) | (+23.99%) | | (−36.0%) | (−14.7%) | (−23.5%) | (−7.0%) | (−79.3%) | (−1.9%) | (−72.2%) |

Results at crosshead speed of 20 mm/min (standard speed) are given in Table 2 below.

TABLE 2

| | Samples | | | | | | | |
|---|---|---|---|---|---|---|---|---|
| | A | D | F | G | H | I | B | C |
| Elongation | 296 | 324 | 236 | 241 | 178 | 67 | 386 | 412 |
| (%) | | | (−27.2%) | (−25.6) | (−45.1%) | (−79.3%) | (+19.1%) | (+27.2%) |
| Modulus | 821.5 | 912.3 | 1089 | 1175.7 | 1143.5 | 1221 | 1031 | 1043 |
| (Young) | | | (+19.4%) | (+28.9%) | (+25.3%) | (+32.9%) | (+13%) | (+14.3%) |
| (MPa) | | | | | | | | |
| Tensile | 40.4 | 47.0 | 42.3 | 51.4 | 43.8 | 45.7 | 42.9 | 45.5 |
| Strength | | | (−10%) | (+9.4%) | (−6.8%) | (−2.8%) | (−8.7%) | (−3.2%) |
| (MPa) | | | | | | | | |
| Toughness | 96.3 | 125.3 | 99.3 | 149 (?) | 84.5 | 28.1 | 143.7 | 142.8 |
| (MPa) | | | (−20.8%) | (+19%) | (−32.6%) | (−77.6%) | (+14.7%) | (+14%) |

Variations

The foregoing description of the invention has been presented describing certain operable and preferred embodiments. It is not intended that the invention should be so limited since variations and modifications thereof will be obvious to those skilled in the art, all of which are within the spirit and scope of the invention.

What is claimed is:

1. Nanoadditive comprising organophilic polymer or copolymer covalently bonded via a linking group to silicate, where the silicate content ranges from 5% to 50% by weight.

2. The nanoadditive of claim 1 where the silicate content ranges from 15 to 30% by weight.

3. The nanoadditive of claim 2 where the linking group comprises reaction product of group A of group A functionalized organophilic polymer or copolymer and group B of group B functionalized silicate.

4. The nanoadditive of claim 3 where group A is selected from the group consisting of epoxide, cyclic anhydride, lactone, amine, alcohol and acid containing moieties and group B is selected from the group consisting of alkoxide, amine, acid, ester, aldehyde, ketone, and lactone containing moieties; where when group A is epoxide containing moiety, group B is selected from the group consisting of alkoxide, amine and acid containing moieties; where when group A is cyclic anhydride containing moiety, group B is selected from the group consisting of alkoxide and amine containing moieties; where when group A is lactone containing moiety, group B is selected from the group consisting of alkoxide and amine containing moieties; where when group A is amine containing moiety, group B is selected from the group consisting of acid, ester, aldehyde, ketone and lactone containing moieties; where when group A is alcohol containing moiety, group B is selected from the group consisting of acid, ester, aldehyde, ketone, and lactone containing moieties; and when group A is acid containing moiety, group B is selected from the group consisting of alkoxide and amine containing moieties.

5. The nanoadditive of claim 4 where the group B is anchored to silicate by an ammonium group separated from group B by an organic spacer moiety containing from 1 to 36 carbon atoms.

6. The nanoadditive of claim 3 where the polymer or copolymer is poly(C₂-C₄-α-olefin-co-hexadiene) copolymer having Mₙ ranging from 5,000 to 2,000,000 grams per mole and PDI ranging from 1.1 to 3.

7. The nanoadditive of claim 6 where the group A functionalized polymer or copolymer is epoxide functionalized poly (propylene-co-hexadiene).

8. The nanoadditive of claim 4 where the polymer or copolymer is poly(propylene-co-hexadiene) having Mₙ ranging from 5,000 to 2,000,000 grams per mole.

9. The nanoadditive of claim 4 where the polymer or copolymer is polypropylene having Mₙ ranging from 5,000 to 4,000,000 grams per mole.

10. The nanoadditive of claim 4 where the group A functionalized polymer or copolymer is cyclic anhydride functionalized said polypropylene.

11. The nanoadditive of claim 4 where the group A functionalized polymer or copolymer is commercially available expoxide functionalized organophilic polymer or copolymer.

12. The nanoadditive of claim 10 where the group A functionalized polymer or copolymer is glycidyl methacrylate having Mₙ ranging from 5,000 to 1,000,000 grams per mole.

13. Nanocomposite comprising from 99 to 90% by weight polypropylene having Mₙ ranging from 5,000 to 4,000,000 grams per mole, and from 1 to 10% by weight nanoclay where silicate layers are exfoliated and the degree of exfoliation is preserved despite extrusion at 200° C. and microinjection at 230° C.

14. The nanocomposite of claim 13 comprising from 98 to 90% by weight of the polypropylene and 2 to 10% by weight of the nanoclay.

15. Nanocomposite comprising from 99 to 90% by weight polypropylene having Mₙ ranging from 5,000 to 4,000,000 grams per mole, and 1 to 10% by weight namely where toughness is increased at least 10% while Young's modulus is decreased less than 15%, compared to neat polypropylene.

16. The nanocomposite of claim 15 comprising from 98 to 90% by weight of the polypropylene and from 2 to 10% of the nanoclay.

17. Nanocomposite comprising the nanoadditive of claim 1 blended polypropylene having Mₙ ranging from 5,000 to 4,000,000 grams per mole, with the weight ratio of said polypropylene to said nanoadditive ranging from 20:1 to 1:1.

18. Nanocomposite comprising the nanoadditive of claim 4 blended with polypropylene having Mₙ ranging from 5,000 to 4,000,000 grams per mole, with the weight ratio of said polypropylene to said nanoadditive ranging from 20:1 to 1:1.

19. Nanocomposite comprising the nanoadditive of claim 7 blended with polypropylene having Mₙ ranging from 5,000 to 4,000,000 grams per mole, with the weight ratio of said polypropylene to said nanoadditive ranging from 20:1 to 1:1.

20. Nanocomposite comprising the nanoadditive of claim 10 blended with polypropylene having Mₙ ranging from 5,000 to 4,000,000 grams per mole, with the weight ratio of said polypropylene to said nanoadditive ranging from 20:1 to 1:1.

21. Epoxy functionalized poly(propylene-co-hexadiene) copolymer having Mₙ ranging from 5,000 to 2,000,000 grams per mole and PDI ranging from 1.1 to 3.

22. A method for preparing a nanoadditive comprising the step of reacting group A functionalized organophilic polymer or copolymer with group B functionalized silicate where group A and group B react to form silicate covalently bonded to the polymer or copolymer.

23. The method of claim 22 where group A is selected from the group consisting of epoxide, cyclic anhydride, lactone, amine, alcohol and acid containing moieties and group B is selected from the group consisting of alkoxide, amine, acid, ester, aldehyde, ketone, and lactone containing moieties; where when group A is epoxide containing moiety, group B is selected from the group consisting of alkoxide, amine and acid containing moieties; where when group A is cyclic anhydride containing moiety, group B is selected from the group consisting of alkoxide and amine containing moieties; where when group A is lactone containing moiety, group B is selected from the group consisting of alkoxide and amine containing moieties; where when group A is amine containing moiety, group B is selected from the group consisting of acid, ester, aldehyde, ketone and lactone containing moieties; where when group A is alcohol containing moiety, group B is selected from the group consisting of acid, ester, aldehyde, ketone, and lactone containing moieties; and when group A is acid containing moiety, group B is selected from the group consisting of alkoxide and amine containing moieties.

24. The method of claim 23 where the group A functionalized polymer or copolymer is epoxide functionalized poly(propylene-co-hexadiene) having Mₙ ranging from 5,000 to 2,000,000 grams per mole and PDI ranging from 1.1 to 1.3.

25. The method of claim 24 where the group B functionalized silicate is 12-aminododecanoic acid or glycine or poly(propylenegylcol)bis(2-aminopropyl ether) ion exchanged under acidic conditions with Na-MMT so that group B is anchored to silicate by an ammonium group.

26. The method of claim 22 where the group A functionalized polymer or copolymer is cyclic anhydride functionalized polypropylene having Mₙ ranging from 5,000 to 4,000,000.

27. The method of claim 25 where the group B functionalized silicate is 12-aminododecanoic acid or glycine or poly(propyleneglycol)bis(2-aminopropyl ether) ion exchanged under acidic conditions with Na-MMT so that group B is anchored to silicate by ammonium group.

28. A method for preparing a nanocomposite comprising the step of blending the nanoadditive of claim 1 with polypropylene having Mₙ ranging from 5,000 to 4,000,000 grams per mole in a weight ratio of said polypropylene to said nanoadditive ranging from 20:1 to 1:1.

29. A method for preparing a nanocomposite comprising the step of blending the nanoadditive of claim 3 with polypropylene having Mₙ ranging from 5,000 to 4,000,000 grams per mole in a weight ratio of said polypropylene to said nanoadditive ranging from 20:1 to 1:1.

30. A method for preparing a nanocomposite comprising the step of blending the nanoadditive of claim 6 with polypropylene having Mₙ ranging from 5,000 to 4,000,000 grams per mole in a weight ratio of said polypropylene to said nanoadditive ranging from 20:1 to 1:1.

31. A method for preparing a nanocomposite comprising the step of blending the nanoadditive of claim 9 with polypropylene having Mₙ ranging from 5,000 to 4,000,000 grams per mole in a weight ratio of said polypropylene to said nanoadditive ranging from 20:1 to 1:1.
